(19) United States
(12) Patent Application Publication
(10) Pub. No.: US 2024/0309504 A1
(43) Pub. Date: Sep. 19, 2024

(54) SUBSTRATE PROCESSING APPARATUS AND GAS SUPPLY METHOD THEREOF

(71) Applicant: TES CO., LTD, Yongin-si (KR)

(72) Inventors: Yeong-Been KIM, Yongin-si (KR); Hyun-Shik AHN, Yongin-si (KR)

(73) Assignee: TES CO., LTD, Yongin-si (KR)

(21) Appl. No.: 18/600,750

(22) Filed: Mar. 10, 2024

(30) Foreign Application Priority Data
Mar. 17, 2023 (KR) 10-2023-0034874

(51) Int. Cl. C23C 16/448; C23C 16/455; C23C 16/52

(52) U.S. Cl. CPC C23C 16/448; C23C 16/45561; C23C 16/52

(57) ABSTRACT

Provided is a gas supply method of a substrate processing apparatus, more particularly, a gas supply method for controlling a supplied amount of gas more precisely when a gas such as a raw material is supplied to a substrate.

### CROSS-REFERENCE TO RELATED APPLICATION

This application is based on and claims priority under 35 U.S.C. § 119 to Korean Patent Application No. 10-2023-0034874, filed on Mar. 17, 2023, in the Korean Intellectual Property Office, the disclosure of which is incorporated by reference herein in its entirety.

### TECHNICAL FIELD

The present disclosure relates to a substrate processing apparatus and a gas supply method of the substrate processing apparatus, and more particularly, to a substrate processing apparatus and a gas supply method of the substrate processing apparatus, for more precisely controlling a gas supply amount when a gas such as a raw material gas is supplied to a substrate.

### BACKGROUND

In general, a substrate processing apparatus accommodates a substrate, or the like in a chamber and supplies various process gases to perform a processing process on the substrate.

In this case, a canister is provided to accommodate a liquid raw material supplied to the chamber, a carrier gas is supplied to the canister depending on a flow rate setting value of carrier gas, and raw material gas vaporized in the canister with the carrier gas is supplied to the chamber.

For example, a vaporization flow rate of the raw material gas that is actually supplied to a chamber is calculated by measuring a flow rate of a mixed gas obtained by mixing the carrier gas and the vaporized raw material gas discharged from the canister and obtaining a difference between a flow measurement value of the mixed gas and a flow rate setting value of the carrier gas.

In a conventional device, the vaporization flow rate of the raw material gas is used in the form of a vaporization flow rate table of the raw material gas in response to a preset flow rate setting value of the carrier gas. Therefore, in the conventional device, the flow rate setting value of the carrier gas required for the vaporization flow rate table of raw material gas is extracted by inserting the vaporization flow rate of the raw material gas required for a process on a substrate into the vaporization flow rate table of the raw material gas, and the carrier gas is supplied to the canister depending on the flow rate setting value of the carrier gas.

However, this method does not consider a temperature change of the canister, and thus when the temperature of the canister changes, there is a problem in that the vaporization amount of the raw material gas changes and the vaporization flow rate of the raw material gas supplied to the chamber changes.

### SUMMARY

To overcome the above problem, an object of the present disclosure is to provide a substrate processing apparatus and a gas supply method of the substrate processing apparatus, for more precisely controlling a flow rate of a vaporized raw material gas by adjusting a vaporized amount of the raw material gas supplied to a chamber by considering a temperature change of the canister with a flow rate of the carrier gas supplied to the canister.

According to an aspect of the present disclosure, a gas supply method of a substrate processing apparatus includes heating a canister accommodating a liquid raw material therein to a predetermined setting temperature, supplying a carrier gas to the canister depending on a predetermined flow rate setting value of the carrier gas, obtaining a flow measurement value of a mixed gas obtained by mixing a vaporized raw material gas discharged from the canister and the carrier gas by measuring a flow rate of the mixed gas, obtaining a calculated value of a vaporization flow rate of the raw material gas by calculating a difference between the flow measurement value of the mixed gas and the flow rate setting value of the carrier gas, and generating a vaporization flow rate table of the raw material gas by corresponding the calculated value of the vaporization flow rate of the raw material gas to the setting temperature and the flow rate setting value of the carrier gas.

The gas supply method may further include heating the canister while changing a setting temperature of the canister from a first setting temperature to an N^{th} setting temperature (N being a natural number greater than 1), wherein, a state in which the canister is heated at any one setting temperature, while the flow rate setting value of the carrier gas is changed from a first flow rate setting value of the carrier gas to an M^{th} flow rate setting value of the carrier gas (M being a natural number greater than 1), the supplying of the carrier gas, the obtaining of the flow measurement value of the mixed gas, the obtaining of the calculated value of the vaporization flow rate of the raw material gas, and the generating of the vaporization flow rate table of the raw material gas may be repeatedly performed.

The gas supply method may further include extracting a flow rate setting value of the carrier gas and a setting temperature of the canister, required in the vaporization flow rate table of the raw material gas, by inserting the vaporization flow rate of the raw material gas required in a process of the substrate processing apparatus into the vaporization flow rate table of the raw material gas, and heating the canister depending on the extracted setting temperature of the canister and supplying the carrier gas to the canister depending on the extracted flow rate setting value of the carrier gas.

According to another aspect of the present disclosure, a substrate processing apparatus includes a chamber providing a processing space for a substrate, a gas supply configured to supply a required process gas to the chamber, and a controller configured to control the gas supply, wherein the gas supply includes a storage configured to store a carrier gas, a mass flow controller (MFC) configured to adjust a supplied amount of the carrier gas, a canister configured to be supplied with the carrier gas and accommodate a liquid raw material, and including a heater configured to heat the liquid raw material and a temperature sensor configured to measure an internal temperature, and a mass flow meter (MFM) located on a flow path on which a mixed gas obtained by mixing a vaporized raw material gas discharged from the canister with the carrier gas and configured to measure a flow rate of the mixed gas.

The controller may be configured to heat the canister to a predetermined setting temperature, supply the carrier gas to the canister depending on a predetermined flow rate setting value of the carrier gas, receive a flow measurement value of the mixed gas from the MFM by measuring a flow rate of the mixed gas obtained by mixing the vaporized raw material gas discharged from the canister with the carrier gas, calculate a calculated value of a vaporization flow rate of the raw material gas by calculating a difference between the flow measurement value of the mixed gas and the flow rate setting value of the carrier gas, and control the MFC by the calculated value of the vaporization flow rate of the raw material gas.

The controller may be configured to generate a vaporization flow rate table of the raw material gas by corresponding the calculated value of the vaporization flow rate of the raw material gas to the setting temperature and the flow rate setting value of the carrier gas.

The controller may be configured to extract a flow rate setting value of the carrier gas and a setting temperature of the canister from the vaporization flow rate table of the raw material gas, by inserting the vaporization flow rate of the raw material gas required in a process of the substrate processing apparatus into the vaporization flow rate table of the raw material gas, heat the canister depending on the extracted setting temperature of the canister, and supply the carrier gas to the canister depending on the extracted flow rate setting value of the carrier gas.

### BRIEF DESCRIPTION OF THE DRAWINGS

Embodiments will be more clearly understood from the following detailed description taken in conjunction with the accompanying drawings in which:

FIG. 1 is a block diagram showing a substrate processing apparatus 1000 according to an embodiment of the present disclosure; and

FIG. 2 is a flowchart showing a gas supply method according to the present disclosure.

### DETAILED DESCRIPTION OF THE EMBODIMENTS

Hereinafter, a gas supply method of a substrate processing apparatus according to an embodiment of the present disclosure will be examined in detail with reference to the drawings.

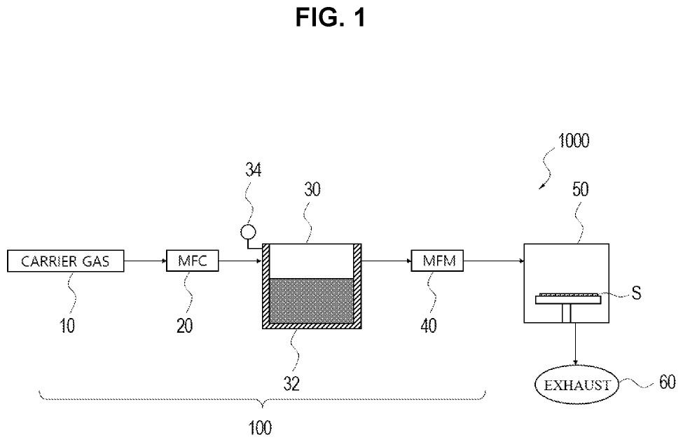

FIG. 1 is a block diagram showing a substrate processing apparatus 1000 according to an embodiment of the present disclosure.

Referring to FIG. 1, the substrate processing apparatus 1000 may include a chamber 50 providing a process space for a substrate S and a gas supply 100 supplying a required process gas to the chamber 50. The substrate processing apparatus 1000 may include a controller (not shown) controlling the gas supply 100 and the chamber 50.

The chamber 50 may accommodate the substrate S inside and perform various processing processes on the substrate S. An exhaust outlet 60 may be connected to one side of the chamber 50 to discharge remaining gas inside the chamber 50 during or after the processing process.

The gas supply 100 may include a storage 10 that stores a carrier gas, a mass flow controller (MFC) 20 that controls a supplied amount of the carrier gas, a canister 30 that accommodates a liquid raw material, and a mass flow meter (MFM) 40 that is located on a flow path on which a mixed gas obtained by mixing a vaporized raw material gas discharged from the canister 30 with the carrier gas and measures a flow rate of the mixed gas.

The storage 10 of the carrier gas may store a carrier gas including an inert gas such as argon or nitrogen.

The carrier gas may be supplied to the canister 30 through the MFC 20.

In other words, it is necessary to adjust the amount of the carrier gas supplied to the canister 30 to correspond to a vaporization flow rate of a raw material gas required by the chamber 50, and in this case, a flow rate of the carrier gas supplied to the canister 30 is adjusted by the MFC 20.

A liquid raw material is accommodated inside the canister 30 and is vaporized, and the vaporized raw material gas and the carrier gas are discharged from the canister 30 together.

The canister 30 may be provided in the form of a housing for accommodating the liquid raw material, but is not limited thereto and may be provided in various forms.

The canister 30 may include a heater 32 that heats a raw material inside. For example, the heater 32 may be located to surround an outer surface of the canister 30. The form and installation method of the heater 32 are described as an example and are not limited thereto.

When the canister 30 is heated by the heater 32, vaporization of a liquid raw material inside the canister 30 may be further facilitated. The temperature at which the canister 30 is heated by the heater 32 may be set in various ways. The canister 30 may further include a temperature sensor 34 that measures the temperature inside the canister 30 or the temperature of the liquid raw material. A heating temperature by the heater 32 may be controlled more precisely by measuring the temperature inside the canister 30 or the temperature of the liquid raw material by the temperature sensor 34.

The mixed gas obtained by mixing a vaporized raw material gas discharged from the canister 30 and the carrier gas may be supplied to the chamber 50.

In this case, the MFM 40 that measures a flow rate of the mixed gas may be installed on a flow path through which the mixed gas is supplied to the chamber 50.

For example, a vaporization flow rate of the raw material gas that is actually supplied to the chamber 50 may be calculated by measuring a flow rate of the mixed gas by the MFM 40 and obtaining a difference between a flow measurement value of the mixed gas and a flow rate setting value of the carrier gas supplied through the MFC 20.

In a conventional device, the vaporization flow rate of the raw material gas is stored in a controller (not shown) in the form of a vaporization flow rate table of the raw material gas in response to a preset flow rate setting value of the carrier gas. Thus, in the conventional device, the flow rate setting value of the carrier gas required for the vaporization flow rate table of raw material gas is extracted by inserting the vaporization flow rate of the raw material gas required for a process on a substrate into the vaporization flow rate table of the raw material gas, and the carrier gas is supplied to the canister 30 depending on the flow rate setting value of the carrier gas.

However, this method does not consider a temperature change of the canister 30, and thus when the temperature of the canister 30 changes, there is a problem in that the vaporization amount of the raw material gas changes and the vaporization flow rate of the raw material gas supplied to the chamber 50 changes. The present disclosure proposes a gas supply method to resolve this problem.

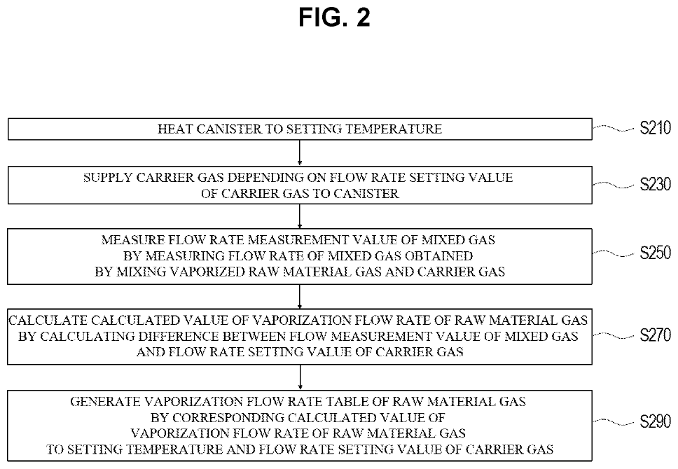

FIG. 2 is a flowchart showing a gas supply method according to the present disclosure.

Referring to FIG. 2, the gas supply method according to the present disclosure may include heating the canister 30 that accommodates the liquid raw material therein to a predetermined setting temperature (S210), supplying a carrier gas to the canister 30 depending on a predetermined flow rate setting value of the carrier gas (S230), calculating a flow measurement value of a mixed gas obtained by mixing a raw material gas discharged from the canister 30 and the carrier gas by measuring a flow rate of the mixed gas (S250), obtaining a calculated value of a vaporization flow rate of the raw material gas by calculating a difference between the flow measurement value of the mixed gas and the flow rate setting value of the carrier gas (S270), and generating a vaporization flow rate table of the raw material gas by corresponding the calculated value of the vaporization flow rate of the raw material gas to the setting temperature and the flow rate setting value of the carrier gas (S290).

First, in the present disclosure, the canister 30 may be heated to a predetermined setting temperature by the heater 32 (S210). In this case, the setting temperature may be appropriately adjusted depending on the type and property of the raw material.

Then, the carrier gas corresponding to a predetermined flow rate setting value of the carrier gas may be supplied to the canister 30 through the MFC 20 (S230).

The flow rate setting value of the carrier gas may be appropriately determined depending on a process performed in the chamber 50.

When the carrier gas is supplied to the canister 30, the raw material gas vaporized in the canister 30 is charged with the carrier gas by using a pressure of the carrier gas. In this case, a flow rate of the mixed gas may be measured by the aforementioned MFM 40 (S250).

The flow measurement value of the mixed gas may correspond to a value obtained by summing an amount of the vaporized raw material gas and a flow rate of the carrier gas.

Accordingly, a calculated value of a vaporization flow rate of the raw material gas that is actually supplied to the chamber 50 from the canister 30 may be obtained by calculating a difference between the flow measurement value of the mixed gas and the flow rate setting value of the carrier gas (S270).

In this case, the aforementioned controller may generate a vaporization flow rate table of the raw material gas by corresponding the calculated value of the vaporization flow rate of the raw material gas to the setting temperature of the canister 30 and the flow rate setting value of the carrier gas (S290) and store the vaporization flow rate table of the raw material gas.

As a result, according to the present disclosure, a table may be generated and stored by corresponding the flow rate setting value of the carrier gas and the setting temperature of the canister 30 to the vaporized amount of the raw material gas, thereby more precisely controlling the vaporized amount of the raw material gas supplied to the chamber 50.

In particular, in the case of a pressure-sensitive process, a change in the carrier gas to change the amount of a raw material gas may affect the process, and thus the table may be usefully used when the amount of the raw material gas is changed while maintaining a process pressure constant through a change in temperature.

The above-described gas supply operation may be performed repeatedly.

For example, the canister 30 may be heated while changing the setting temperature from a first setting temperature to an N^{th} setting temperature (N being a natural number greater than 1). Each setting temperature may be set at a predetermined temperature interval such as 10° C. or 20° C. This temperature interval may be adjusted in various ways.

In the present disclosure, when the canister 30 is heated to any one of the setting temperatures, the aforementioned operations may be repeatedly performed while changing the flow rate setting value of the carrier gas from the first flow rate setting value of the carrier gas to the M^{th} flow rate setting value of the carrier gas (M being a natural number greater than 1).

That is, when the flow rate setting value of carrier gas is determined as any one setting value, operation S230 of supplying the carrier gas, operation S250 of calculating the flow measurement value of the mixed gas, operation S270 of obtaining the calculated value of the vaporization flow rate of the raw material gas, and operation S290 of generating the vaporization flow rate table of the raw material gas may be repeatedly performed.

As a result, in the present disclosure, the calculated value of the vaporization flow rate of the raw material gas may be obtained while changing the setting temperature of the canister 30 and the flow rate setting value of the carrier gas, and thus the vaporization flow rate table of the raw material gas may be manufactured by corresponding the calculated value of the vaporization flow rate of the raw material gas to the setting temperature and the flow rate setting value of the carrier gas.

Accordingly, according to the present disclosure, the controller of the substrate processing apparatus 1000 may extract the flow rate setting value of the carrier gas and the setting temperature of a canister from the vaporization flow rate table of the raw material gas, by inserting the vaporization flow rate of the raw material gas required in the processing process on the substrate S into the vaporization flow rate table of the raw material gas.

The controller may heat the canister 30 by the heater 32 depending on the extracted setting temperature of the canister and supply the carrier gas to the canister 30 through the MFC 20 depending on the extracted flow rate setting value of the carrier gas.

According to the present disclosure having the aforementioned configuration, a flow rate of a vaporized raw material gas may be more precisely controlled by adjusting a vaporized amount of the raw material gas supplied to a chamber by considering a temperature change of the canister with a flow rate of the carrier gas supplied to the canister.

Although the present disclosure has been described above with reference to exemplary embodiments, those skilled in the art may modify and change the present disclosure in various ways without departing from the spirit and scope of the present disclosure as set forth in the claims described below. Therefore, when the modified implementation basically includes the elements of the claims of the present disclosure, it should be considered to be included in the technical scope of the present disclosure.

What is claimed is:

1. A gas supply method of a substrate processing apparatus, the gas supply method comprising:
heating a canister accommodating a liquid raw material therein to a predetermined setting temperature;
supplying a carrier gas to the canister depending on a predetermined flow rate setting value of the carrier gas;
obtaining a flow measurement value of a mixed gas obtained by mixing a vaporized raw material gas discharged from the canister and the carrier gas by measuring a flow rate of the mixed gas;
obtaining a calculated value of a vaporization flow rate of the raw material gas by calculating a difference between the flow measurement value of the mixed gas and the flow rate setting value of the carrier gas; and
generating a vaporization flow rate table of the raw material gas by corresponding the calculated value of the vaporization flow rate of the raw material gas to the setting temperature and the flow rate setting value of the carrier gas.

2. The gas supply method of claim 1, further comprising heating the canister while changing the setting temperature of the canister from a first setting temperature to an N^{th} setting temperature (N being a natural number greater than 1),
wherein, in a state in which the canister is heated at any one setting temperature,
while the flow rate setting value of the carrier gas is changed from a first flow rate setting value of the carrier gas to an M^{th} flow rate setting value of the carrier gas (M being a natural number greater than 1), the supplying of the carrier gas, the obtaining of the flow measurement value of the mixed gas, the obtaining of the calculated value of the vaporization flow rate of the raw material gas, and the generating of the vaporization flow rate table of the raw material gas are repeatedly performed.

3. The gas supply method of claim 2, further comprising:
extracting the flow rate setting value of the carrier gas and the setting temperature of the canister from the vaporization flow rate table of the raw material gas, by inserting the vaporization flow rate of the raw material gas required in a process of the substrate processing apparatus into the vaporization flow rate table of the raw material gas; and
heating the canister depending on the extracted setting temperature of the canister and supplying the carrier gas to the canister depending on the extracted flow rate setting value of the carrier gas.

4. A substrate processing apparatus comprising:
a chamber providing a processing space for a substrate;
a gas supply configured to supply a required process gas to the chamber; and
a controller configured to control the gas supply,
wherein the gas supply includes a storage configured to store a carrier gas, a mass flow controller (MFC) configured to adjust a supplied amount of the carrier gas, a canister configured to be supplied with the carrier gas and accommodate a liquid raw material, and including a heater configured to heat the liquid raw material and a temperature sensor configured to measure an internal temperature, and a mass flow meter (MFM) located on a flow path on which a mixed gas obtained by mixing a vaporized raw material gas discharged from the canister with the carrier gas and configured to measure a flow rate of the mixed gas, and
the controller is configured to heat the canister to a predetermined setting temperature, supply the carrier gas to the canister depending on a predetermined flow rate setting value of the carrier gas, receive a flow measurement value of the mixed gas from the MFM by measuring a flow rate of the mixed gas obtained by mixing the vaporized raw material gas discharged from the canister with the carrier gas, obtain a calculated value of a vaporization flow rate of the raw material gas by calculating a difference between the flow measurement value of the mixed gas and the flow rate setting value of the carrier gas, and control the MFC by the calculated value of the vaporization flow rate of the raw material gas.

5. The substrate processing apparatus of claim 4, wherein the controller is configured to generate a vaporization flow rate table of the raw material gas by corresponding the calculated value of the vaporization flow rate of the raw material gas to the setting temperature and the flow rate setting value of the carrier gas.

6. The substrate processing apparatus of claim 5, wherein the controller is configured to extract the flow rate setting value of the carrier gas and the setting temperature of the canister from the vaporization flow rate table of the raw material gas, by inserting the vaporization flow rate of the raw material gas required in a process of the substrate processing apparatus into the vaporization flow rate table of the raw material gas, heat the canister depending on the extracted setting temperature of the canister, and supply the carrier gas to the canister depending on the extracted flow rate setting value of the carrier gas.
